(19) United States
(12) Patent Application Publication
(10) Pub. No.: US 2024/0183897 A1
(43) Pub. Date: Jun. 6, 2024

(54) WAFER SCALE ACTIVE THERMAL INTERPOSER WITH THERMAL ISOLATION STRUCTURES

(71) Applicant: Advantest Test Solutions, Inc., San Jose, CA (US)

(72) Inventors: Karthik Ranganathan, San Jose, CA (US); Aritomo Kikuchi, San Jose, CA (US); Merlin Wallner, San Jose, CA (US); Rajan Surve, San Jose, CA (US); Samer Kabbani, Laguna Niguel, CA (US); Paul Ferrari, San Jose, CA (US); Ikeda Hiroki, San Jose, CA (US); Kiyokawa Toshiyuki, San Jose, CA (US); Gregory Cruzan, San Jose, CA (US)

(21) Appl. No.: 18/440,191

(22) Filed: Feb. 13, 2024

Related U.S. Application Data
(63) Continuation-in-part of application No. 17/528,002, filed on Nov. 16, 2021.
(60) Provisional application No. 63/115,813, filed on Nov. 19, 2020.

(51) Int. Cl. G01R 31/28

(52) U.S. Cl. CPC G01R 31/2875; G01R 31/2856; G01R 31/2877

(57) ABSTRACT

A system for testing circuits of an integrated circuit semiconductor wafer includes a tester system testing the circuits of the wafer and a test stack coupled to the tester system. The test stack includes a wafer probe for contacting a first surface of the wafer and for probing individual circuits of the circuits of the wafer, a wafer scale active thermal interposer layer operable to contact a second surface of the wafer and containing a plurality of thermal zones corresponding to a die layout of the wafer and further operable to selectively heat areas of the wafer. The thermal zones are thermally isolated using a plurality of thermal resistance structures disposed between the thermal zones.

### RELATED APPLICATION(S)

This application is a Continuation in Part of and claims priority to co-pending, commonly-owned U.S. application Ser. No. 17/528,002 (Attorney Docket AATS-0107-01U00US), entitled “Wafer Scale Active Thermal Interposer for Device Testing,” to Kabbani et al., filed Nov. 16, 2021, which in turn claims priority to U.S. Provisional Application No. 63/115,813, (Attorney Docket AATS-0107-00.00US), filed Nov. 19, 2020, entitled “Wafer Scale Active Thermal Interposer.”

This application is related to U.S. Pat. No. 9,291,667, filed Mar. 4, 2014, entitled “Adaptive Thermal Control,” Ser. No. 14/196,955 (Attorney Docket No. ATST-JP0097.US). This application is also related to U.S. Pat. No. 11,674,999, filed Apr. 20, 2022, entitled “Wafer Scale Active Thermal Interposer for Device Testing,” Ser. No. 17/725,164 (Attorney Docket No. AATS-0107-02C01US). All such applications and/or patents are hereby incorporated herein by reference in their entireties.

### FIELD OF INVENTION

Embodiments of the present invention relate to the field of integrated circuit manufacturing and testing. More specifically, embodiments of the present invention relate to systems and methods for testing integrated circuit devices in wafer embodiments.

### BACKGROUND

It is common to subject integrated circuits, either packaged or unpackaged, to environmental testing as an operation in a manufacturing process. Typically in such testing, the integrated circuit devices are subject to electrical testing, e.g., “test patterns,” to confirm functionality while being subjected to environmental stress. For example, an integrated circuit is heated and/or cooled to its specification limits while being electrically tested. In some cases, e.g., for qualification testing, an integrated circuit may be stressed beyond its specifications, for example, to determine failure points and/or to establish a “guard band” on its environmental specifications.

Traditionally, such testing has included placing one or more integrated circuits and their associated test interface(s) and support hardware into an environmental chamber. The environmental chamber would heat and/or cool the integrated circuit(s) under test, known as or referred to as a device under test, or “DUT,” as well as the test interface and support hardware, to the desired test temperature. Unfortunately, use of such test chambers has numerous drawbacks. For example, the limits and/or accuracy of such testing may be degraded due to environmental limits of the test interface circuits and/or devices. The substantial air volumes, mass of mounting structures, and necessary interface devices in an environmental test chamber may impede rapid changes in the testing environment, thus limiting the testing rate. Further, placing and removing DUTs and testing apparatus into and out of such test chambers further limits rates of testing, and requires complex and expensive mechanisms to perform such insertions and removals.

Recently, environmental test systems have been created that heat and/or cool a DUT directly, without placing the DUT and test apparatus into an environmental chamber. Such “chamber-less” test systems overcome many of the limitations of chamber-based testing. Unfortunately, chamber-less test systems introduce testing difficulties, particularly related to cooling integrated circuits under test.

Cooling of integrated circuits under test is typically performed by thermally coupling a cooling structure, e.g., metal, to the device under test. A cooling fluid, e.g., comprising glycol, is circulated through a portion of the cooling structure. To adjust the temperature of the cooling structure, the temperature of the cooling fluid may be adjusted. The flow of the cooling fluid may also be adjusted, e.g., increased, reduced, started, and/or stopped.

It is desirable to perform environmental testing at a wafer level, for example, comprising tens to potentially thousands of dice, beneficially increasing manufacturing throughput. In addition, testing at a wafer level may identify defective or sub-standard die at the wafer level, avoiding the expense of additional manufacturing and test operations for such devices.

Unfortunately, precise heating and/or cooling of an individual die within a wafer is not available under the conventional art, rendering wafer-level testing under environmental conditions unavailable.

### SUMMARY OF THE INVENTION

Therefore, what is needed are systems and methods for testing individual die of a wafer. Further, what is needed is maintaining temperature control of the dice of a wafer during testing thereof. What is further needed is a wafer scale active thermal interposer device with thermal isolation for performing the temperature control. What is additionally needed are systems and methods for wafer scale active thermal interposer devices with thermal isolation operable to selectively control different portions of a wafer to different temperatures. There is a further need for systems and methods for wafer scale active thermal interposer devices with thermal isolation that are compatible and complementary with existing systems and methods of testing integrated circuits.

In accordance with embodiments of the present invention, a wafer scale active thermal interposer (ATI) device for use in testing a wafer device under test (DUT) includes a formation including one or more layers and including a plurality of thermal zones configured to apply thermal energy to a plurality of dice of the wafer DUT during the testing thereof. The plurality of thermal zones corresponds to a die layout of the wafer DUT. A first thermal zone of the plurality of thermal zones is configured to apply thermal energy to a first thermal region of the wafer DUT, and a second thermal zone of the plurality of thermal zones is configured to apply thermal energy to a second thermal region of the wafer DUT. The second thermal zone is configured to control a temperature of the second thermal region of the wafer DUT independently of a temperature of the first thermal region, and the first thermal zone is configured to control a temperature of the first thermal region of the wafer DUT independently of a temperature of the second thermal region. The formation further includes a plurality of thermal resistance structures located between the plurality of thermal zones. The plurality of thermal resistance structures is configured to limit conductance of thermal energy between the plurality of thermal zones.

Embodiments include the above and further include wherein the plurality of thermal zones covers the plurality of dice of the wafer DUT.

Embodiments include the above and further include wherein the first thermal zone corresponds to more than one die of the plurality of dice of the wafer DUT and less than the plurality of dice of the wafer DUT.

Embodiments include the above and further include wherein the first thermal zone corresponds to a single die of the plurality of dice of the wafer DUT.

Embodiments include the above and further include wherein the first thermal zone corresponds to a portion a single die of the plurality of dice of the wafer DUT.

Embodiments include the above and further include wherein the plurality of thermal resistance structures includes a plurality of trenches formed in the formation and disposed between the plurality of thermal zones.

Embodiments include the above and further include wherein the plurality of trenches is formed completely through of the one or more layers of the formation.

Embodiments include the above and further include wherein the plurality of trenches is formed partially through the one or more layers of the formation.

Embodiments include the above and further include an EMI shield layer.

Embodiments include the above and further include wherein the plurality of thermal resistance structures includes a plurality of structures raised above a surface of the formation and disposed between the plurality of thermal zones.

Embodiments include the above and further include wherein the plurality of thermal resistance structures includes a same material as a surface of the formation.

Embodiments include the above and further include wherein the plurality of thermal resistance structures includes a plurality of substantially similar holes formed in the formation and disposed between the plurality of thermal zones.

Embodiments include the above and further include an EMI shield layer and wherein the EMI shield layer includes conductive elements disposed in areas between a plurality of holes having non-circular cross sections.

In accordance with embodiments of the present invention, a system for testing circuits of an integrated circuit semiconductor wafer includes a tester system for testing the circuits of the wafer, and a test stack coupled to the tester system. The test stack includes a wafer probe for contacting a first surface of the wafer and for probing individual circuits of the circuits of the wafer, and a thermal interposer device operable to contact a second surface of the wafer and including a plurality of heating zones corresponding to a die layout of the wafer and operable to selectively heat a plurality of regions of the wafer during the testing. The thermal interposer device includes a plurality of thermal resistance structures disposed between the plurality of heating zones and configured to limit conductance of thermal energy between the plurality of heating zones, a cold plate disposed adjacent to a surface of the thermal interposer device and operable to cool the wafer, and a thermal controller for selectively heating and maintaining temperatures of the plurality of regions of the wafer by controlling cooling of the cold plate and by controlling selective heating of the plurality of heating zones of the thermal interposer device.

Embodiments include the above and further include wherein the plurality of thermal resistance structures includes a plurality of trenches formed in the thermal interposer device, the plurality of trenches disposed between the plurality of heating zones of the thermal interposer device.

Embodiments include the above and further include wherein the thermal interposer device includes one or more layers and wherein the plurality of trenches is formed completely through the one or more layers of the thermal interposer device.

Embodiments include the above and further include wherein the thermal interposer device includes one or more layers and wherein the plurality of trenches is formed partially through the one or more layers of the thermal interposer device.

Embodiments include the above and further include wherein the thermal interposer device further includes an EMI shield layer.

Embodiments include the above and further include wherein the plurality of thermal resistance structures includes a plurality of structure elements raised above a surface of the thermal interposer device, the plurality of structure elements disposed between the plurality of heating zones of the thermal interposer device.

Embodiments include the above and further include wherein the plurality of thermal resistance structures includes a same material as a surface of the thermal interposer device.

Embodiments include the above and further include wherein the plurality of thermal resistance structures includes a plurality of substantially similar holes formed in the thermal interposer device.

Embodiments include the above and further include wherein the thermal interposer device includes an EMI shield layer and wherein the EMI shield layer includes conductive elements disposed in areas between the plurality of substantially similar holes.

### BRIEF DESCRIPTION OF THE DRAWINGS

The accompanying drawings, which are incorporated in and form a part of this specification, illustrate embodiments of the invention and, together with the description, serve to explain the principles of the invention. Unless otherwise noted, the drawings may not be drawn to scale.

FIG. 1 illustrates an exemplary block diagram of elements of an automated test system environment that may serve as a platform for embodiments in accordance with the present invention.

FIG. 2 illustrates an exemplary block diagram cross sectional view of a novel wafer scale active thermal interposer device, in accordance with embodiments of the present invention.

FIG. 3 illustrates an exemplary block diagram of elements of an automated test system environment including a wafer scale active thermal interposer device, in accordance with embodiments of the present invention.

FIG. 4 illustrates a plan view of an exemplary layout of controllable regions of a wafer scale active thermal interposer device and an associated exemplary wafer, in accordance with embodiments of the present invention.

FIG. 5 illustrates an exemplary plan view layout of controllable regions of a wafer scale active thermal interposer device and an associated wafer, in accordance with embodiments of the present invention.

FIG. 6 illustrates an exemplary plan view layout of controllable regions of a wafer scale active thermal interposer device and an associated wafer, in accordance with embodiments of the present invention.

FIG. 7A illustrates an exemplary computer-controlled process for testing circuits of an integrated circuit semiconductor wafer comprising multiple integrated circuit dice using a wafer scale active thermal interposer device, in accordance with embodiments of the present invention.

FIG. 7B illustrates an exemplary computer-controlled method for testing circuits of an integrated circuit semiconductor wafer using a wafer scale active thermal interposer device, in accordance with embodiments of the present invention.

FIG. 8 illustrates an exemplary plan view layout of controllable regions of an exemplary wafer scale active thermal interposer with thermal isolation device, in accordance with embodiments of the present invention.

FIG. 9A illustrates an exemplary plan view of an exemplary embodiment of a thermal resistance structure for a wafer scale thermal interposer device, in accordance with embodiments of the present invention.

FIG. 9B illustrates an exemplary side-sectional view of an exemplary embodiment of a thermal resistance structure for a wafer scale thermal interposer device, in accordance with embodiments of the present invention.

FIG. 10 illustrates an exemplary side-sectional view of an exemplary embodiment of a thermal resistance structure for a wafer scale thermal interposer device in accordance with embodiments of the present invention.

FIGS. 11A, 11B, and 11C illustrate exemplary side-sectional views of an exemplary embodiment of a thermal resistance structure for a wafer scale thermal interposer device, in accordance with embodiments of the present invention.

FIG. 12 illustrates a block diagram of an exemplary electronic system, which may be used as a platform to implement and/or as a control system for embodiments of the present invention.

### DETAILED DESCRIPTION

Reference will now be made in detail to various embodiments of the invention, examples of which are illustrated in the accompanying drawings. While the invention will be described in conjunction with these embodiments, it is understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the invention, numerous specific details are set forth in order to provide a thorough understanding of the invention. However, it will be recognized by one of ordinary skill in the art that the invention may be practiced without these specific details. In other instances, well known methods, procedures, components, and circuits have not been described in detail as not to unnecessarily obscure aspects of the invention.

Some portions of the detailed descriptions which follow (e.g., processes 700 and 750) are presented in terms of procedures, steps, logic blocks, processing, and other symbolic representations of operations on data bits that may be performed on computer memory. These descriptions and representations are the means used by those skilled in the data processing arts to most effectively convey the substance of their work to others skilled in the art. A procedure, computer executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, data, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout the present invention, discussions utilizing terms such as “testing” or “heating” or “maintaining temperature” or “bringing” or “capturing” or “storing” or “reading” or “analyzing” or “generating” or “resolving” or “accepting” or “selecting” or “determining” or “displaying” or “presenting” or “computing” or “sending” or “receiving” or “reducing” or “detecting” or “setting” or “accessing” or “placing” or “testing” or “forming” or “mounting” or “removing” or “ceasing” or “stopping” or “coating” or “processing” or “performing” or “generating” or “adjusting” or “creating” or “executing” or “continuing” or “indexing” or “translating” or “calculating” or “measuring” or “gathering” or “running” or the like, refer to the action and processes of, or under the control of, a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The meaning of “non-transitory computer-readable medium” should be construed to exclude only those types of transitory computer-readable media which were found to fall outside the scope of patentable subject matter under 35 U.S.C. § 101 in In re Nuijten, 500 F.3d 1346, 1356-57 (Fed. Cir. 1007). The use of this term is to be understood to remove only propagating transitory signals per se from the claim scope and does not relinquish rights to all standard computer-readable media that are not only propagating transitory signals per se.

Wafer Scale Active Thermal Interposer with Thermal Isolation Structures

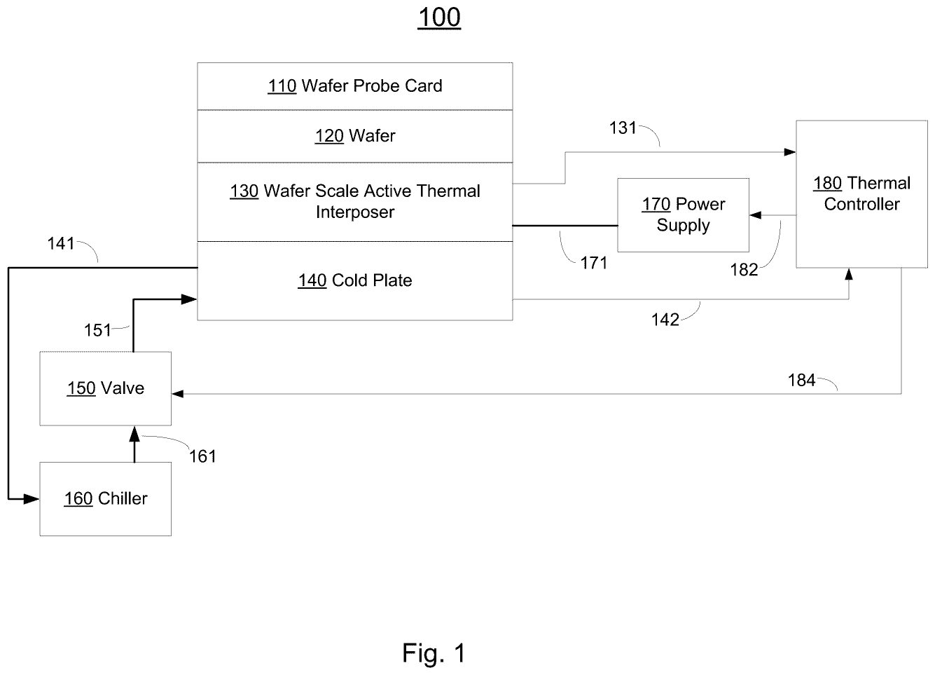

FIG. 1 illustrates an exemplary block diagram of elements of an automated test system environment 100, which utilizes a wafer scale active thermal interposer device for selectively and independently controlling temperatures of a die layout within a wafer device under test (DUT), that may serve as a platform for embodiments in accordance with the present invention. Test system 100 receives and tests a semiconductor wafer 120, for example comprising a plurality of integrated circuit devices or dice having a prescribed die layout. A wafer probe card 110 is coupled to wafer 120, e.g., utilizing test pads formed on the wafer 120, to send and receive test signals and power to integrated circuit devices embodied within or on wafer 120. Wafer probe card 110 is typically electronically coupled to, and tests, a single die of wafer 120 at a time, although that is not required.

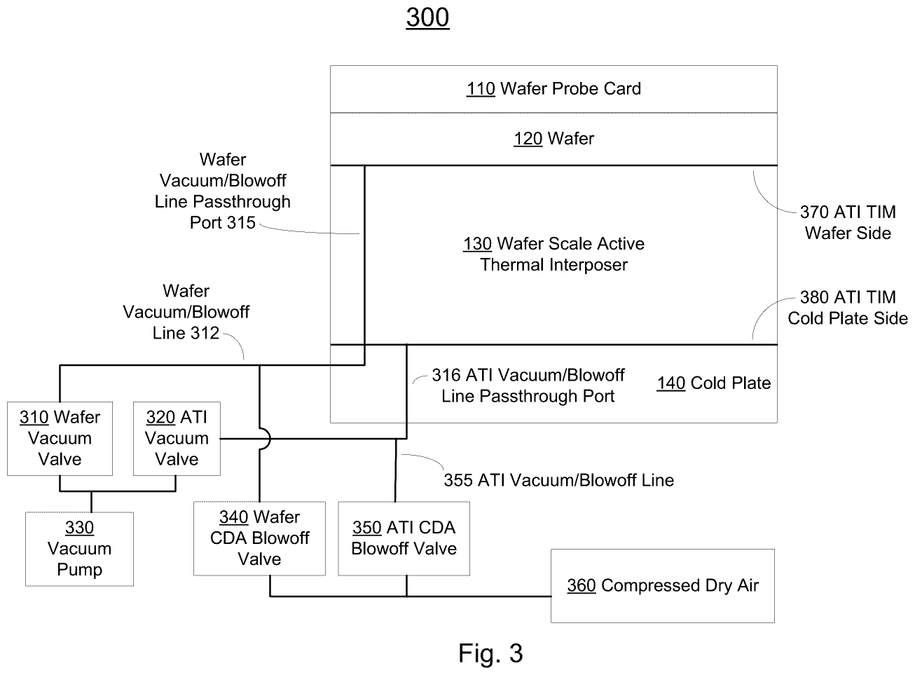

In accordance with embodiments of the present invention, a novel wafer scale active thermal interposer device 130 is coupled to the backside of wafer 120. Wafer scale active thermal interposer device 130 may be customized for a specific design (e.g., die layout) of wafer 120, in some embodiments. In some embodiments, there may be a thermal interface material (not shown, see FIG. 3) disposed between wafer scale active thermal interposer device 130 and wafer 120. Such a thermal interface material, if present, is designed to improve thermal coupling between wafer scale active thermal interposer device 130 and wafer 120.

In some embodiments, wafer scale active thermal interposer device 130 may comprise a base layer of aluminum nitride (AlN) with tungsten and/or molybdenum traces. A high temperature co-fired ceramic (HTCC) process may be utilized. Such embodiments may be suitable for testing comparatively higher power devices. In some embodiments, a low temperature co-fired ceramic (LTCC) process, e.g., comprising aluminum oxide (Al₂0₃) may be utilized. Such embodiments may be suitable for testing comparatively lower power devices.

Wafer scale active thermal interposer device 130 is further coupled to a cold plate 140, e.g., cold plate 140 is disposed adjacent to active thermal interposer device 130. In some embodiments, there may be a thermal interface material (not shown) disposed between wafer scale active thermal interposer device 130 and cold plate 140. Such a thermal interface material, if present, is designed to improve thermal coupling between wafer scale active thermal interposer device 130 and cold plate 140.

In an embodiment, a cooling fluid, e.g., comprising glycol, although other fluids, including air, may be used, is generally circulated through cold plate 140. To adjust the temperature of the cold plate 140, the temperature of the cooling fluid may be adjusted, in some embodiments. In some embodiments, as illustrated in FIG. 1, the flow rate of the cooling fluid may also be adjusted, e.g., increased, reduced, started, and/or stopped. For example, a speed of a pump and/or fan may be adjusted. In an embodiment, chiller 160 cools the cooling fluid, e.g., to −60 degrees C. The cooling fluid flows through 161 to valve 150. Valve 150, under the control of thermal controller 180 via path 184, regulates the flow 151 of cooling fluid to cold plate 140. After cycling through cold plate 140, the cooling fluid is returned via path 141, e.g., a pipe or conduit suitable for containing the cooling fluid, to the chiller 160. In this manner, thermal controller 180 may cool wafer 120 during testing via cooling action from chiller 160 and the cold plate 140.

In accordance with embodiments of the present invention, thermal controller 180 may implement some or all of the control processes described in U.S. Pat. No. 9,291,667 entitled “Adaptive Thermal Control,” incorporated herein by reference in its entirety.

In some embodiments, cold plate 140 may comprise an evaporator and/or phase change cooling system. In such embodiments, chiller 160 may comprise a compressor and/or radiator, for example.

Wafer scale active thermal interposer device 130 functions to apply heat energy to one or more temperature regions of wafer 120. The temperature regions may correspond, in location and/or shape, with the dice (e.g., die layout) on the wafer 120. To accomplish such heating, wafer scale active thermal interposer device 130 comprises one or more heating elements, as further described below. The heating elements of wafer scale active thermal interposer device 130 correspond to the temperature regions of wafer 120 and therefore correspond to the die layout and dimensions of the wafer. In some embodiments, the heating elements comprise resistive traces on a ceramic substrate. In some embodiments, the heating elements may be Peltier devices, capable of cooling as well. However, any suitable heating and/or cooling technology is well suited to embodiments in accordance with the present invention. Wafer scale active thermal interposer device 130 also functions to couple heat energy from wafer 120 to cold plate 140 for cooling.

Wafer scale active thermal interposer device 130 further comprises a plurality of temperature measurement devices (not shown), e.g., thermocouples. The plurality of temperature measurement devices are configured to measure temperatures of regions of wafer 120. The plurality of temperature measurement devices may be located within or in close proximity to the heating elements of wafer scale active thermal interposer device 130, in some embodiments. In other embodiments, wafer scale active thermal interposer device 130 may comprise temperature measurement devices that are not within or in close proximity to the heating elements of wafer scale active thermal interposer device 130. Each of the plurality of temperature measurement devices sends a temperature signal 131 to thermal controller 180. Thermal controller 180 may receive a temperature measurement 142 of cold plate 140. Wafer probe card 110, wafer 120, wafer scale active thermal interposer device 130, and cold plate 140 may be collectively known as or referred to as a test stack or test head when coupled together as illustrated in FIG. 1.

Test system 100 further comprises a thermal controller 180. Thermal controller 180 is an intelligent device and sends control signals 182 to power supply 170 to supply electrical power 171 to one or more heating elements of wafer scale active thermal interposer device 130. Each heating element of wafer scale active thermal interposer device 130 may be individually controlled. Accordingly, more power signal(s) 171 may represent multiple different power signals. There may be more than one power supply, in some embodiments. Based on temperature signal 131 from one or more of the plurality of temperature measurement devices, thermal controller 180 may control power supply 170 to change the power supplied to a heating element. Power supply 170 may change a voltage level and/or pulse width modulate a voltage supplied to a heating element to control heating of the heating element, in some embodiments. Thermal controller 180 also controls the amount of heat energy extracted via path 141 from cold plate 140. For example, thermal controller 180 controls the temperature of cold plate 140. Thermal controller 180 controls valve 150 based on temperature signal 131.

It is to be appreciated that cold plate 140 extracts heat, through wafer scale active thermal interposer device 130, from substantially all of wafer 120. In addition, cold plate 140 typically has a large thermal mass, and does not change temperature quickly. Accordingly, heating elements of wafer scale active thermal interposer device 130 may often be required to overcome the cooling effect of cold plate 140. In some embodiments, different regions of a wafer 120 may be heated and/or cooled to different temperatures based on the selective heating capability of the heaters of the wafer scale active thermal interposer device 130 and the cooling function of cold plate 140. For example, one region of wafer 120 may be heated to 100 degrees C., e.g., via a heater element within wafer scale active thermal interposer device 130, while another region of wafer 120 may be allowed to cool toward the temperature of cold plate 140 with no heat applied to such region by wafer scale active thermal interposer device 130. Such differential heating and/or cooling of different regions of wafer 120 may produce a thermal gradient across or between regions of wafer 120, in some embodiments.

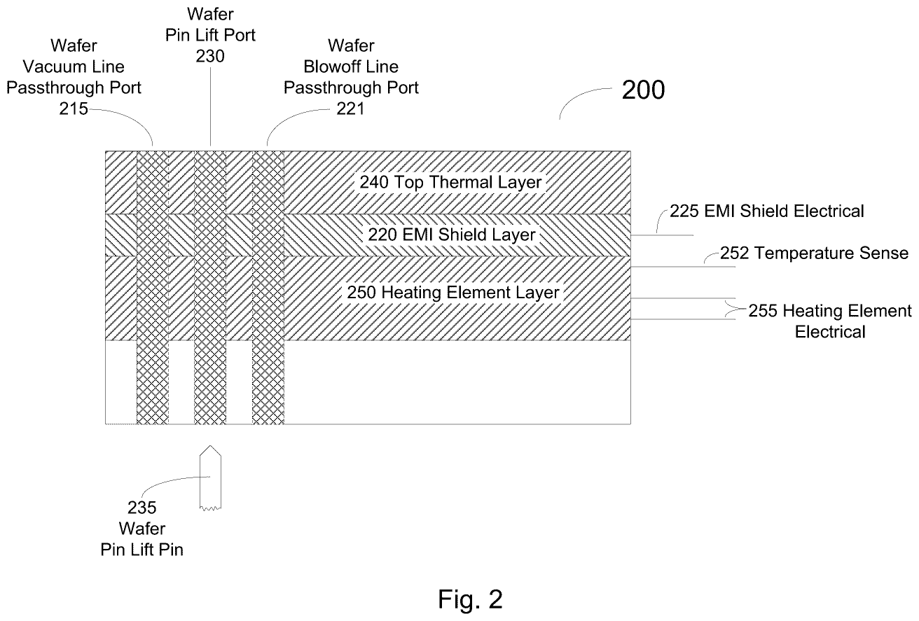

FIG. 2 illustrates an exemplary block diagram cross sectional view of a novel wafer scale active thermal interposer device 200, in accordance with embodiments of the present invention. Wafer scale active thermal interposer device 200 generally performs equivalent functions to wafer scale active thermal interposer device 130 of FIG. 1. Wafer scale active thermal interposer device 200 comprises a heating element layer 250, and this layer may be referred to as the formation layer or body layer. Heating element layer 250 comprises a plurality of discrete and separately controllable heating elements configured to apply heat energy to a wafer, e.g., wafer 120 of FIG. 1. The heating elements may comprise resistive traces or other suitable types of heaters. The plurality of heating elements are coupled to a plurality of electrical signals 255, for providing controlled power to the heating elements such that the elements are separately controllable. Heating element layer 250 may include low resistance traces, e.g., from electrical signals 255 to the actual heating elements, in some embodiments. Heating element layer 250 also comprises a plurality of temperature measurement devices, e.g., thermocouples, (not shown), which are coupled to control elements via a plurality of temperature sense signals 252. As discussed above, the sizes, shapes, and/or positions of the heating elements (thermal or heating zones) of the wafer scale active thermal interposer 200 correspond to and are customized for the die layout of the wafer DUT.

In accordance with embodiments of the present invention, wafer scale active thermal interposer device 200 may comprise a novel electromagnetic interference (EMI) shield layer 220 to address signal interference caused by the heater elements. Each of the plurality of heating elements in layer 250 may utilize currents of many tens of amperes. In embodiments of the present invention that utilize switching such currents to control temperature, e.g., pulse width modulation, such switching may induce unwanted electromagnetic noise signals that are deleterious to the operation and/or test of integrated circuits on a wafer, e.g., wafer 120 of FIG. 1, coupled to the wafer scale active thermal interposer device 200. In some embodiments, EMI shield layer 220 comprises a solid layer of conductor, e.g., conductive traces similar to those utilized in heating element layer 250. In some embodiments, EMI shield layer 220 comprises a grid of conductive elements. The grid may be sized to attenuate desired wavelength(s) of electromagnetic interference. EMI shield layer 220 may have an electrical connection 225, e.g., to ground, in some embodiments.

Wafer scale active thermal interposer device 200 comprises a top thermal layer 240. Thermal layer 240 functions to couple heat energy from heating element layer 250 to a wafer under test and vice versa. Thermal layer 240 is non-conductive, in some embodiments. Thermal layer 240 should have a high degree of co-planarity in order to facilitate good thermal conduction to a wafer and to promote good vacuum hold down of the wafer, in some embodiments.

Wafer scale active thermal interposer device 200 is compatible and complementary with conventional elements of wafer scale test equipment. Accordingly, in some embodiments, wafer scale active thermal interposer device 200 may comprise one or more wafer vacuum line passthrough ports 215. Wafer vacuum line passthrough ports 215 couple to one or more conventional vacuum lines, as is typically used to hold down a wafer in place during testing. For example, wafer vacuum line passthrough port 215 mates with a vacuum port of a conventional cold plate, e.g., cold plate 140 of FIG. 1. There may be a plurality of wafer vacuum line passthrough ports 215 in an instance of wafer scale active thermal interposer device 200, for example three arranged in an equilateral triangle, in some embodiments. A wafer vacuum line passthrough port 215 typically extends through wafer scale active thermal interposer device 200.

In some embodiments, wafer scale active thermal interposer device 200 may comprise one or more wafer blowoff line passthrough ports 221. Wafer blowoff line passthrough port 221 couples to a conventional wafer blowoff line, as is typically used to break a vacuum seal of a wafer, prior to removing the wafer from the test system. For example, wafer blowoff line passthrough port 221 mates with a wafer blowoff line port of a conventional cold plate, e.g., cold plate 140 of FIG. 1. There may be a plurality of wafer blowoff line passthrough ports 221 in an instance of wafer scale active thermal interposer device 200, for example three arranged in an equilateral triangle, in some embodiments. A wafer blowoff line passthrough port 221 typically extends through wafer scale active thermal interposer device 200.

Wafer scale active thermal interposer device 200 may also comprise a wafer pin lift port 230, in some embodiments. Wafer pin lift port 230 may be aligned with a similar port or channel in a cold plate, e.g., cold plate 140 of FIG. 1. Wafer pin lift port 230 enables a wafer lift pin 235 to raise a wafer above the top of the wafer scale active thermal interposer device 200. For example, wafer handling equipment typically needs a gap under a wafer in order to lift the wafer and move the wafer to another station in a wafer manufacturing and test process. The wafer lift pin 235 typically extends from or through a cold plate, e.g., cold plate 140 of FIG. 1, and/or from a chuck mechanism (not shown). In accordance with some embodiments of the present invention, the wafer lift pin 235 may be lengthened, in contrast to a conventional lift pin, to account for the thickness of wafer scale active thermal interposer device 200. There may be a plurality of wafer pin lift ports 230 in an instance of wafer scale active thermal interposer device 200, for example three arranged in an equilateral triangle, in some embodiments. A wafer pin lift port 230 typically extends through wafer scale active thermal interposer device 200.

With respect to the wafer scale active thermal interposer device 200, wafer vacuum line passthrough ports 215, wafer blowoff line passthrough ports 221 and/or wafer pin lift ports 230 may be combined in any suitable combination, in accordance with embodiments of the present invention. For example, a wafer vacuum line passthrough ports 215 may be combined with a wafer blowoff line passthrough port 221.

FIG. 3 illustrates an exemplary block diagram of elements of an automated test system environment 300 including a wafer scale active thermal interposer device, in accordance with embodiments of the present invention. FIG. 3 illustrates functional components of a wafer vacuum hold down and blowoff systems in combination with wafer scale active thermal interposer device 130.

Test system environment 300 comprises a vacuum pump 330 coupled to wafer vacuum valve 310 and wafer scale active thermal interposer (ATI) vacuum valve 320. Wafer vacuum valve 310 is coupled to wafer vacuum/blowoff line passthrough port 315 of wafer scale active thermal interposer device 130 via path 312. In the illustrated embodiment, the vacuum passthrough and blowoff passthrough ports are combined, although this is not required and such ports may be separate. To hold down a wafer 120 prior to and during test, wafer vacuum valve 310 is opened, enabling a pressure differential between ambient atmosphere and vacuum to hold down the wafer 120 to the wafer scale active thermal interposer device 130.

ATI vacuum valve 320 is coupled to ATI vacuum/blowoff line passthrough port 316 of cold plate 140. To hold down ATI device 130 prior to and during test, ATI vacuum valve 320 is opened, enabling a pressure differential between ambient atmosphere and/or ATI device 130 and vacuum to hold down the ATI device 130 to the cold plate 140.

Compressed dry air source (CDA) 360 is coupled to wafer CDA blowoff valve 340 and to ATI CDA blowoff valve 350. To blow the wafer 120 off of the ATI device 130, the wafer vacuum valve 310 is closed and the wafer CDA blowoff valve 340 is opened, coupling compressed dry air through the vacuum/blowoff line passthrough port 315 to break the prior vacuum seal. To remove the wafer scale active thermal interposer device 130 from the cold plate 140, for example, to change to a different wafer scale thermal interposer, the ATI vacuum valve 320 is closed and the ATI CDA blowoff valve 350 is opened, coupling compressed dry air through ATI vacuum/blowoff line 355 to the ATI vacuum/blowoff line passthrough port 316 to break the prior vacuum seal.

In accordance with embodiments of the present invention, test system 300 may comprise a thermal interface material (TIM) 370 disposed at the ATI/wafer interface and/or a thermal interface material 380 disposed at the ATI/cold plate interface. The thermal interface material is operable to provide thermal coupling, e.g., has a high thermal conductance, and provides mechanical compliance to compensate for irregularities in the adjoining surfaces. The thermal interface material may be considered to be separate from the wafer scale active thermal interposer device 130, in some embodiments. For example, a thermal interface material 370 may be applied to the wafer scale active thermal interposer device 130 after the wafer scale active thermal interposer device 130 is placed in the test system 300. Any suitable thermal interface material may be used, including those comprising indium foil and/or carbon nanotubes, in accordance with embodiments of the present invention. Thermal interface material 370 may differ from thermal interface material 380 in composition and/or thickness, in some embodiments.

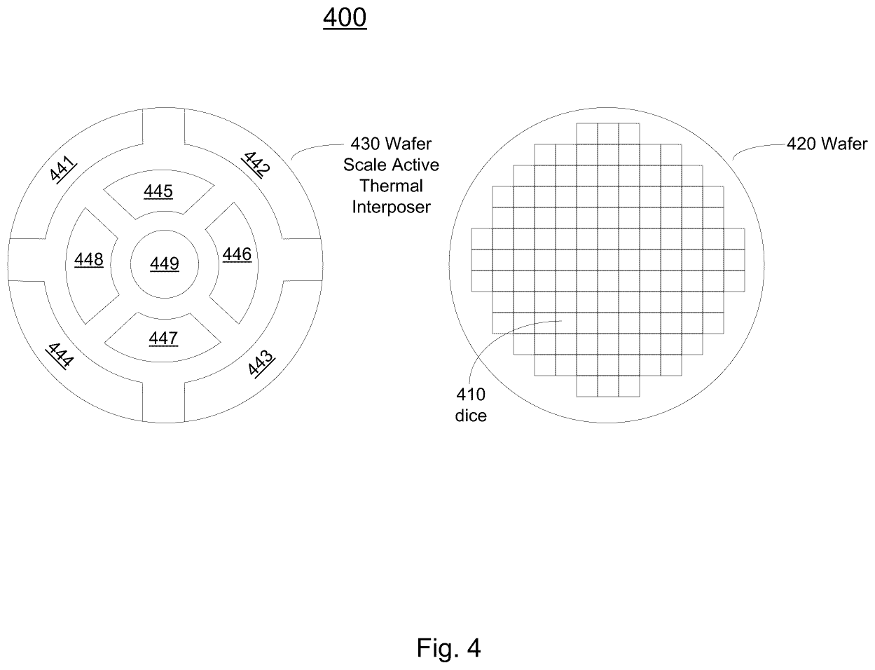

FIG. 4 illustrates a plan view layout of an exemplary layout 400 of controllable thermal regions of a wafer scale active thermal interposer device 430 and an associated exemplary wafer 420, in accordance with embodiments of the present invention. The wafer scale active thermal interposer device 430 generally corresponds to wafer scale active thermal interposer device 130 as previously described in FIGS. 1, 2, and 3. The wafer scale active thermal interposer device 430 is configured to be used in testing of wafer 420 and contain controllable thermal regions that correspond to the die layout of the wafer, as discussed.

Wafer 420 comprises a plurality of discrete dice 410 in accordance with a die layout. Dice 410 may be characterized as relatively small and/or designed to operate at relatively low power levels. Examples of such integrated circuits may include microcontrollers, dynamic RAMs, application-specific integrated circuits, and the like. Due to their small size and/or low power operational characteristics, such integrated circuits may not require application of large amounts of heat energy to achieve desired test temperatures. In addition, small integrated circuit die may be physically smaller than a desired minimum size of a heating element as used in wafer scale active thermal interposer device 430.

Wafer scale active thermal interposer device 430 comprises a plurality of selective heatable regions (thermal regions or zones) 441, 442, 443, 444, 445, 446, 447, 448 and 449. The number of heatable regions and their layout and size and shape are exemplary, and may be customized to the die layout of the wafer 420. Wafer scale active thermal interposer device 430 is configured to heat and/or cool portions of wafer 420 corresponding to one or more of the selective heatable regions 441, 442, 443, 444, 445, 446, 447, 448 and 449. In accordance with embodiments of the present invention, each heatable region (e.g., thermal zone) of wafer scale active thermal interposer device 430 may correspond to more than one die of wafer 420 or may correspond to a sub portion of a single die. For example, heatable region 449 of wafer scale active thermal interposer device 430 is configured to selectively apply heat energy to approximately nine dice (exemplary only) of wafer 420 when coupled to wafer 420 in a test system.

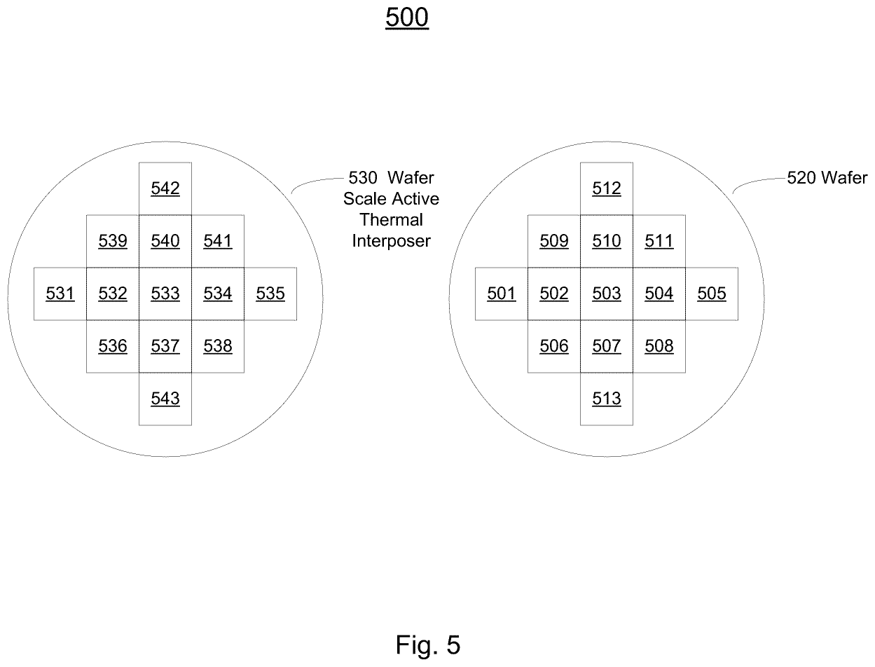

FIG. 5 illustrates an exemplary plan view layout 500 of controllable regions of an exemplary wafer scale active thermal interposer device 530 and an associated exemplary wafer 520, in accordance with embodiments of the present invention. The wafer scale active thermal interposer device 530 generally corresponds to wafer scale active thermal interposer device 130 as previously described in FIGS. 1, 2, and 3. The wafer scale active thermal interposer device 530 is configured to be used in testing of wafer 520.

Wafer 520 comprises a plurality of dice 501-513. Dice 501-513 are arranged in a die layout as shown and may be characterized as relatively large and/or designed to operate at relatively high power levels. Examples of such integrated circuits may include central processing units (CPUs), graphics processing units (GPUs), Network Processing Units (NPUs), multi-core processing units, power semiconductors, and the like. Due to their large size and/or high power operational characteristics, such integrated circuits may require application of large amounts of heat energy to achieve desired test temperatures.

Wafer scale active thermal interposer device 530 comprises a plurality of selectable heatable regions (thermal zones) 531, 532, 533, 534, 535, 536, 537, 538, 539, 540, 541, 542, and 543. The number of heatable regions and their layout is exemplary and corresponds to the die layout of the wafer 520. Wafer scale active thermal interposer device 530 is configured to heat and/or cool portions of wafer 520 corresponding to one or more of the heatable regions 531, 532, 533, 534, 535, 536, 537, 538, 539, 540, 541, 542, and 543. In accordance with embodiments of the present invention, each heatable region of wafer scale active thermal interposer device 530 may correspond to one die of wafer 520 in location and shape or may correspond to multiple die or portions of one die. For example, heatable region 542 of wafer scale active thermal interposer device 530 is configured to selectively apply heat energy to die 512 of wafer 520 when coupled to wafer 520 in a test system. In this novel manner, wafer scale active thermal interposer device 530 may selectively apply sufficient heat energy to large and/or high-power die to achieve desired test temperatures while in wafer form. The discrete dice of the wafer 520 may be selectively heated during testing by the discrete and separately controlled heating elements of the wafer scale active thermal interposer device 530.

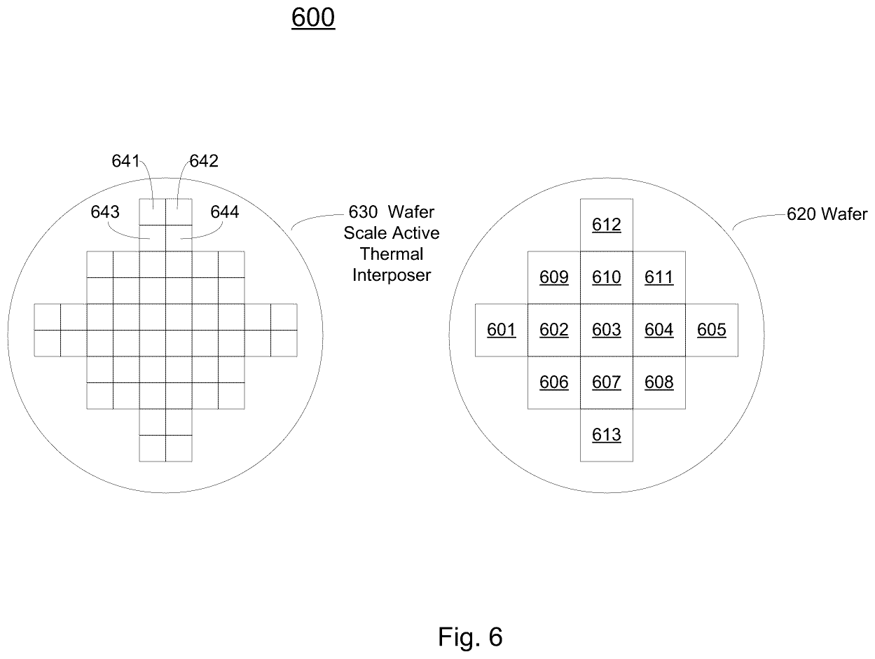

FIG. 6 illustrates an exemplary plan view layout 600 of controllable regions of a wafer scale active thermal interposer device 630 and an associated wafer 620, in accordance with embodiments of the present invention. The wafer scale active thermal interposer device 630 generally corresponds to wafer scale active thermal interposer device 130 as previously described in FIGS. 1, 2, and 3. The wafer scale active thermal interposer device 630 is configured to be used in testing of wafer 620.

Wafer 620 comprises a plurality of dice 601, 602, 603, 604, 605, 606, 607, 608, 609, 610, 611, 612, and 613 in accordance with a die layout as shown. Dice 601, 602, 603, 604, 605, 606, 607, 608, 609, 610, 611, 612, and 613 may be characterized as relatively large and/or designed to operate at relatively high power levels. Examples of such integrated circuits may include central processing units (CPUs), graphics processing units (GPUs), Network Processing Units (NPUs), multi-core processing units, power semiconductors, and the like. Due to their large size and/or high power operational characteristics, such integrated circuits may require application of large amounts of heat energy to achieve desired test temperatures.

Large and complex integrated circuits frequently comprise a plurality of functional units, e.g., multiple processing cores, which are physically distinct. It may be desirable to test such functional units in whole or in partial isolation from other function units of a die. For example, a GPU comprising multiple floating point units may be designed to utilize a single floating point unit at times during operation, and turn off other floating point units, e.g., those that are not currently required, in order to reduce power consumption. It may be desirable to test the GPU under similar thermal conditions. For example, it may be desirable to run functional tests on a portion of the GPU corresponding to an operational floating point unit at a high temperature, while other portions of the GPU are at a different, e.g., lower, temperature, simulating non-operation.

In addition, the heat energy required to achieve a desirable test temperature for large and/or high powered die may exceed the capacity of a single heating element of a wafer scale thermal interposer. For example, conductive traces of a wafer scale thermal interposer may have current capacity limitations. Further, other components of a single heating element and/or a wafer scale thermal interposer may limit an amount of heat energy generated to be less that required to supply sufficient heat energy to achieve a desired temperature of a die under test.

Wafer scale active thermal interposer device 630 comprises a plurality of heatable regions or thermal zones, e.g., heatable regions 641, 642, 643, and 644. The number of heatable regions and their layout is exemplary. Wafer scale active thermal interposer device 630 is configured to selectively heat and/or cool portions of wafer 620 corresponding to one or more of the heatable regions 641, 642, 643, and 644. In accordance with embodiments of the present invention, each heatable region of wafer scale active thermal interposer device 630 corresponds to a portion of one die of wafer 620. For example, heatable region 642 of wafer scale active thermal interposer device 630 is configured to selectively apply heat energy to the right upper quadrant of die 612 of wafer 620 when coupled to wafer 620 in a test system. In this novel manner, wafer scale active thermal interposer device 630 may selectively apply sufficient heat energy to portions of large and/or high-power die to achieve desired test temperatures, including different temperatures within a single die, while in wafer form. In this way, the heatable regions correspond to the die layout of wafer 620.

In accordance with embodiments of the present invention, areas of a wafer, e.g., wafer 620 of FIG. 6, which are not under test may nevertheless be opportunistically preconditioned to a desirable temperature. For example, while testing die 612 (FIG. 6) at a desired testing temperature, embodiments in accordance with the present invention may bring die 609 to a desired test temperature while die 609 is not being tested, e.g., prior to testing die 609. It is appreciated that semiconductor die have a thermal mass, and do not change temperature instantaneously. In this novel manner, a plurality of die may be opportunistically preconditioned to a desirable temperature, e.g., in advance of their testing, to increase testing throughput. Such opportunistic temperature preconditioning may beneficially increase a rate of testing of multiple dice, for example, by eliminating a time delay between testing of a first and a second die required to bring the second die, or portion thereof, to a desirable test temperature.

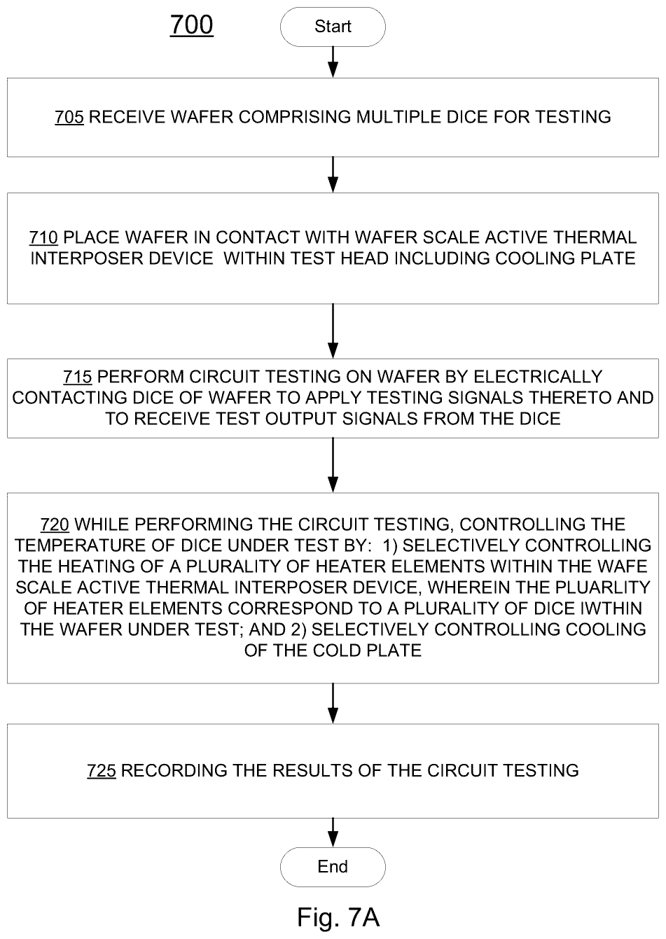

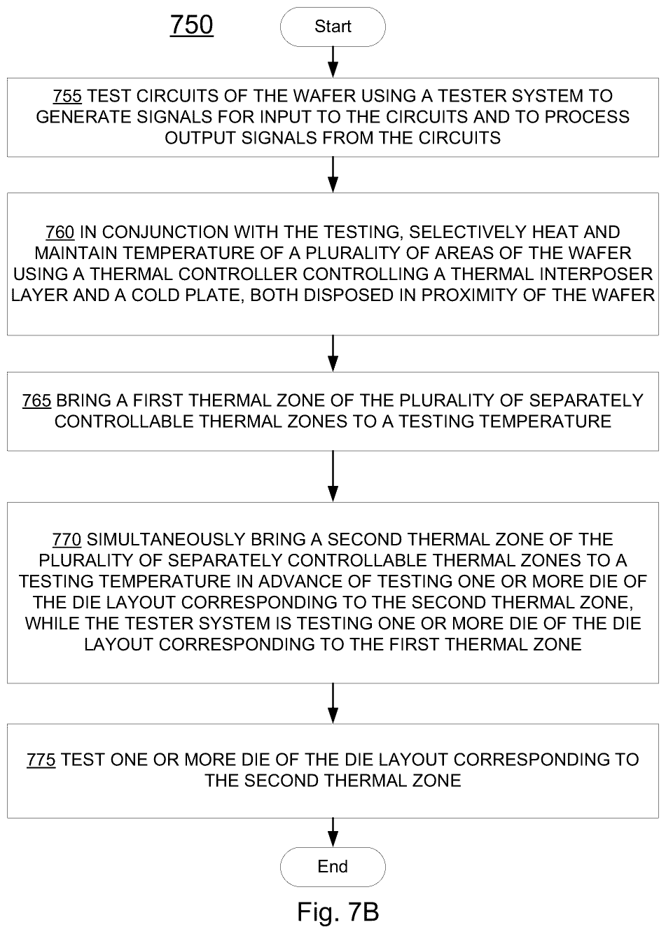

FIG. 7A illustrates an exemplary computer-controlled process 700 for testing circuits of an integrated circuit semiconductor wafer comprising multiple integrated circuit dice using a wafer scale active thermal interposer device, in accordance with embodiments of the present invention. In 705, a wafer comprising multiple dice for testing is received for testing, e.g., within an automated test equipment, for example, automated test environment 100 of FIG. 1.

In block 710, a wafer, e.g., wafer 120 of FIG. 1, is placed in contact with a wafer scale active thermal interposer device, e.g., wafer scale active thermal interposer device 130 (FIG. 1). In block 715, circuit testing is performed on the wafer by electrically contacting dice of the wafer to apply testing signals thereto and to receive test output signals from the dice.

In block 720, while performing the circuit testing, the temperature of dice under test is controlled by a thermal controller operating by: 1) selectively controlling the heating of a plurality of heater elements within the wafer scale active thermal interposer device, wherein the plurality of heater elements correspond to a plurality of dice within the wafer under test; and 2) selectively controlling cooling of the cold plate. In optional block 725, the results of the circuit testing are recorded.

FIG. 7B illustrates an exemplary computer controlled method 750 for testing circuits of an integrated circuit semiconductor wafer using a wafer scale active thermal interposer device, in accordance with embodiments of the present invention. In block 755, the circuits of a wafer are tested by using a tester system to generate signals for input to the circuits and to process output signals from the circuits.

In block 760, in conjunction with the testing, a plurality of areas of the wafer are selectively heated and have their temperatures maintained by using a thermal controller selectively controlling discrete heater elements of a thermal interposer layer and a cold plate, both disposed in proximity of the wafer. The thermal interposer comprises a plurality of separately controllable thermal zones wherein each thermal zone is operable to be selectively heated and temperature maintained by the thermal controller. The thermal zones may correspond in location and shape to dice on the wafer being tested. The selective heating may include bringing a first set of thermal zones of the plurality of separately controllable thermal zones to a testing temperature while the tester system is testing a first die of the die layout corresponding to the first set of thermal zones, simultaneously and opportunistically bringing a second set of thermal zones of plurality of separately controllable thermal zones to a testing temperature in advance of testing a second die of the die layout corresponding to the second set of thermal zones.

In optional block 765, a first thermal zone of the plurality of separately controllable thermal zones is brought to a testing temperature. In optional block 770, a second thermal zone of the plurality of separately controllable thermal zones to is simultaneously brought to a testing temperature in advance of testing one or more die of the die layout corresponding to the second thermal zone, while the tester system is testing one or more die of the die layout corresponding to the first thermal zone. In optional block 775, one or more die of the die layout corresponding to the second thermal zone are tested.

In accordance with embodiments of the present invention, it may be beneficial to place or form thermal resistance structures between some or all of active thermal regions or zones, e.g., thermal regions or zones 531, 532, 533, 534, 535, 536, 537, 538, 539, 540, 541, 542, and 543, as illustrated in FIG. 5 to thermally isolate the regions during selective heating thereof. Such thermal resistance structures decrease heat conduction among thermal zones. For example, a thermal resistance structure may reduce or inhibit thermal conduction from thermal region 542 to thermal region 540 (FIG. 5). The thermal resistance structures may improve the capability of maintaining different temperatures in different thermal regions of a wafer scale active thermal interposer device.

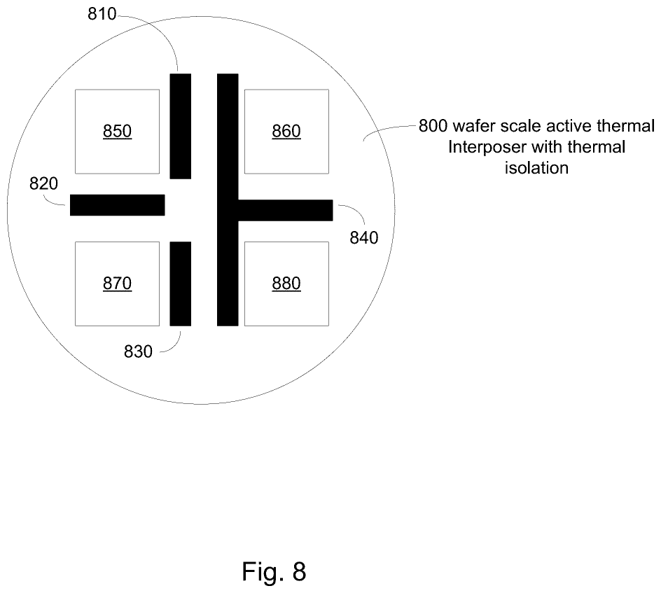

FIG. 8 illustrates an exemplary plan view layout of controllable regions of an exemplary wafer scale active thermal interposer 800 with thermal isolation device structures 810, 820, 830, 840, in accordance with embodiments of the present invention. Wafer scale active thermal interposer device 800 comprises thermal regions or zones 850, 860, 870, and 880. The number of zones illustrated is exemplary and as discussed, the size and shape and placement of the zones correspond to a die layout of the wafer. Thermal regions or zones 850, 860, 870, and 880 are generally equivalent to thermal regions or zones 531, 532, 533, 534, 535, 536, 537, 538, 539, 540, 541, 542, and 543, as illustrated in FIG. 5. Thermal regions or zones 850, 860, 870, and 880 are generally equivalent to the plurality of selective heatable regions 441, 442, 443, 444, 445, 446, 447, 448 and 449, as illustrated in FIG. 4. Thermal regions or zones 850, 860, 870, and 880 are generally equivalent to the plurality of heatable regions 641, 642, 643, and 644, as illustrated in FIG. 6. Thermal regions or zones 850, 860, 870, and 880 may be any suitable shape, and there may be any suitable number of thermal regions or zones. In accordance with embodiments of the present invention, a thermal zone may correspond to a die on a wafer, a portion of a die on a wafer, more than one die on a wafer, or may correspond to more than one region of multiple dice on a wafer.

In addition to thermal regions or zones 850, 860, 870, and 880, thermal interposer 800 comprises a plurality of thermal resistance structures, e.g., exemplary thermal resistance structures 810, 820, 830, and 840. Exemplary thermal resistance structure 810, 820, 830, and 840 function to limit a flow of thermal energy from one thermal region, e.g., thermal region 850, to one or more other thermal regions, e.g., thermal region 870. The plurality of thermal resistance structures may be continuous, e.g., as illustrated in exemplary thermal resistance structure 840, or discontinuous, as illustrated in exemplary thermal resistance structures 810, 820, and 830. Although illustrated in generally rectilinear form (in plan view), thermal resistance structures may have any suitable shape, including curve segments, zig-zag patterns, serpentine patterns, and the like, in accordance with embodiments of the present invention.

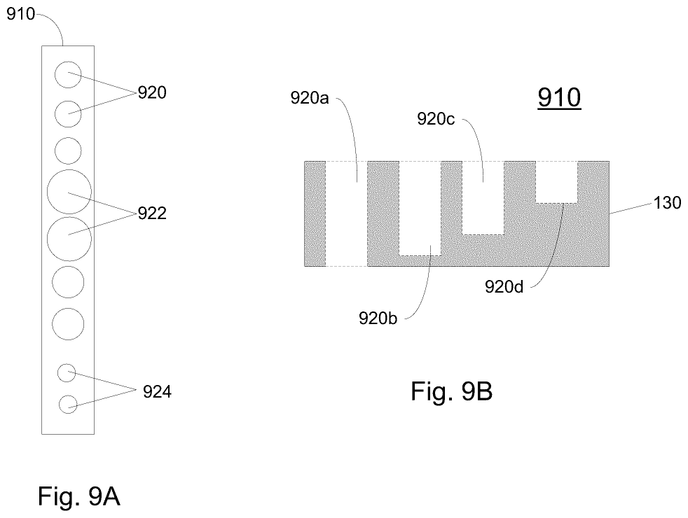

FIG. 9A illustrates an exemplary plan view of an exemplary embodiment of a thermal resistance structure, e.g., thermal resistance structure 910, in accordance with embodiments of the present invention. In this embodiment, the thermal resistance structure is made up of many holes. Thermal resistance structure 910 may correspond to one or more of thermal resistance structures 810, 820, 830 and/or 840 (FIG. 8). Thermal resistance structure 910 comprises a plurality of holes 920, 922, 924. The holes 920, 922, 924 may be formed completely or partially through a wafer scale active thermal interposer device, in accordance with embodiments of the present invention. For example, the holes 920, 922, 924 may be formed completely or partially through some or all of layers 240, 220, and/or 250 (FIG. 2) of a wafer scale active thermal interposer device. Although holes 920 are illustrated in plan view as having circular cross sections, this is not required. In accordance with embodiments of the present invention, holes 920, 922, 924 may have any suitable cross section, including non-regular and/or non-symmetrical cross sections. The plurality of holes 920, 922, 924 may have different cross-sectional shapes, in embodiments.

For example, if holes 920, 922, 924 are formed by subtractive manufacturing methods, e.g., drilling, holes comprising circular cross section may be more straight-forward to produce. If holes 920, 922, 924 are formed during additive manufacturing processes, other hole shapes, e.g., rectangular or polygonal cross sections, may be advantageous to such manufacturing processes. Embodiments in accordance with the present invention are well suited to all such manufacturing processes.

Holes 920, 922, 924 may have any suitable diameter and/or cross-sectional area, in accordance with embodiments of the present invention. The holes 920, 922, 924 may have any suitable spacing, including non-regular spacing, from one another. For example, holes 922 are illustrated as being closer together than holes 924. In accordance with embodiments of the present invention, holes 920, 922, 924 may have greater cross-sectional area and/or closer spacing in one portion of thermal resistance structure 910 than in other portions of thermal resistance structure 910. For example, holes 922 are illustrated as having a larger cross sectional area than holes 924. In this novel manner, a thermal resistance of thermal resistance structure 910 may be varied across the extent of thermal resistance structure 910.

FIG. 9B illustrates an exemplary side-sectional view of an exemplary embodiment of a thermal resistance structure 910, in accordance with embodiments of the present invention. FIG. 9B illustrates a variety of possible holes 920, e.g., holes 920a, 920b, 920c, and 920d. Embodiments in accordance with the present invention may comprise holes completely or partially through some or all of layers 240, 220, and/or 250 (FIG. 2) of a wafer scale active thermal interposer device. For example, hole 920a is formed completely through active thermal interposer device 130 (FIG. 1). Holes 920b, 920c, and 920d are formed partially through portions, e.g., layers, of active thermal interposer device 130. In some embodiments, all holes 920 may be formed to a same depth into a wafer scale active thermal interposer device. In some embodiments, holes 920 may be formed to differing depths into a wafer scale active thermal interposer device.

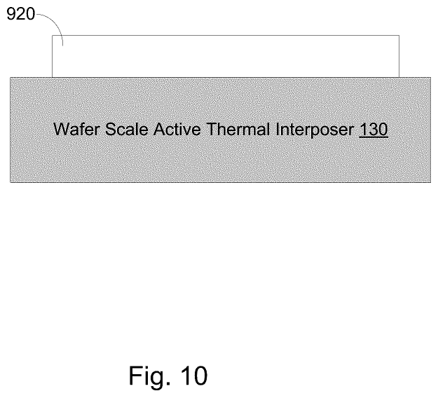

FIG. 10 illustrates an exemplary side-sectional view of an exemplary embodiment of a thermal resistance structure, e.g., thermal resistance structure 920, in accordance with embodiments of the present invention. Thermal resistance structure 920 is a “wall-like” structure formed above a main body of an active thermal interposer, e.g., active thermal interposer device 130 (FIG. 1) and extends above a surface of the interposer body. In some embodiments, thermal resistance structure 920 comprises the same material(s) as active thermal interposer device 130.

For example, it is known to form a wafer scale active thermal interposer from multiple, e.g., eight, layers of aluminum nitrite (AlN), which are subsequently pressed together and sintered. If active thermal interposer device 130 is formed via a layering process, thermal resistance structure 920 may be formed by additional layers in its region. In some embodiments, thermal resistance structure 920 may be added to wafer scale active thermal interposer device 130 in additional operation(s) after manufacture of a main portion of wafer scale active thermal interposer device 130.

Embodiments of FIG. 10 may generally extend from a device under test side of wafer scale active thermal interposer device 130, although that is not required. The height of thermal resistance structure 920 may be limited to avoid interference with structures of a device under test, and/or to allow elements of the wafer scale active thermal interposer device 130 and/or thermal interface material, to contact elements of the device under test. Exemplary heights for thermal resistance structure 920 can be in the range of 1 to 10 mm above a surface of active thermal interposer device 130, in embodiments.

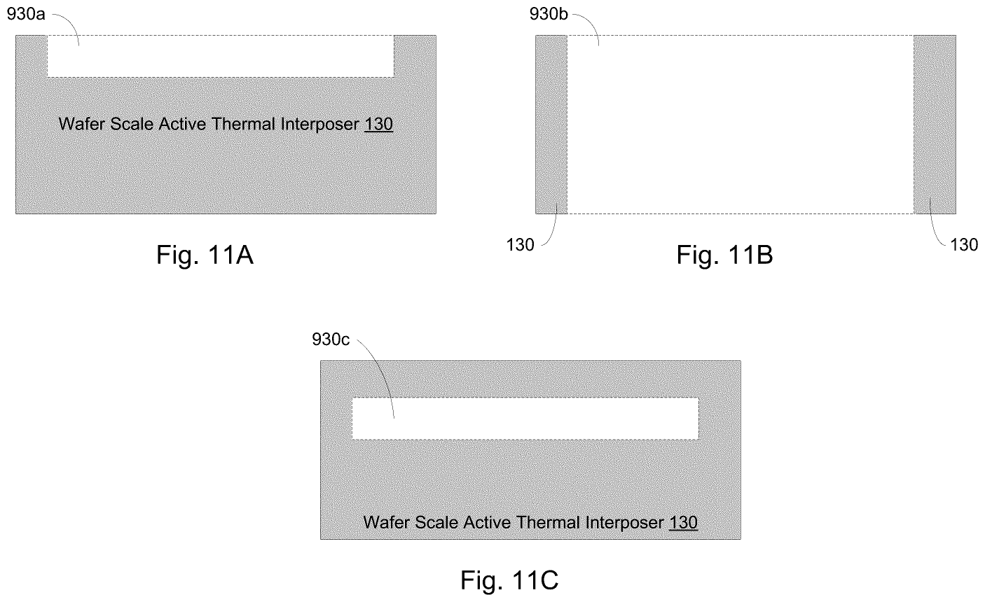

FIGS. 11A and 11B illustrate exemplary side-sectional views of an exemplary embodiment of a thermal resistance structure, e.g., thermal resistance structure 930a-c, in accordance with embodiments of the present invention. In this embodiment, the thermal resistance structures are trenches or trench like structures. Thermal resistance structure 930a-c may be formed completely or partially through a wafer scale active thermal interposer device, in accordance with embodiments of the present invention. For example, thermal resistance structure 930a-c may be formed completely or partially through some or all of layers 240, 220, and/or 250 (FIG. 2) of a wafer scale active thermal interposer device. In contrast to the exemplary embodiments of FIGS. 9A and 9B, thermal resistance structure 930a-c comprises a single “trench” or continuous narrow channel, whereas FIGS. 9A and 9B illustrate a plurality of separate holes. Generally, the term trench is used to mean or refer to a void of material, e.g., a hole or ditch, although it may be filled, e.g., with a different type of material than what was removed (or not placed). Generally, the length of such a trench is much greater than its width or depth.

FIG. 11A illustrates a side-sectional view of an exemplary embodiment of a thermal resistance structure, e.g., thermal resistance structure 930a, in accordance with embodiments of the present invention. Thermal resistance structure 930a comprises a trough, trench, or long hole inside wafer scale active thermal interposer device 130 (FIG. 1). Thermal resistance structure 930a does not extend completely through wafer scale active thermal interposer device 130. For embodiments of a thermal resistance structure, e.g., thermal resistance structure 930a, that do not extend completely through wafer scale active thermal interposer device 130, such embodiments may start at either face of wafer scale active thermal interposer device 130, e.g., a first face configured to be close to a device under test, or an opposite face, configured to be disposed away from a device under test.

In some embodiments, a trench thermal resistance structure, e.g., thermal resistance structure 930a, may be filled, or partially filled, with a material having a different thermal conductivity than a thermal conductivity of wafer scale active thermal interposer device 130. For example, filling thermal resistance structure 930a with a material having a lower thermal conductivity than a thermal conductivity of wafer scale active thermal interposer device 130 may provide improved structural characteristics for a wafer scale active thermal interposer in comparison to an empty thermal resistance structure 930a, while providing reduced thermal conductivity between thermal regions.

FIG. 11B illustrates a side-sectional view of an exemplary embodiment of a thermal resistance structure, e.g., thermal resistance structure 930b, in accordance with embodiments of the present invention. Thermal resistance structure 930b comprises a trough, trench, or long hole inside active thermal interposer device 130 (FIG. 1). Thermal resistance structure 930b extends completely through active thermal interposer device 130. In some embodiments, a thermal resistance structure, e.g., thermal resistance structure 930c, may not extend to either face of active thermal interposer device 130, as illustrated in FIG. 11C.

In some embodiments, conductive elements of EMI shield layer 220 (FIG. 2) may be routed in between thermal resistance structures 930a, 930b, and/or 930c, to maintain continuity of an EMI shield layer between separate thermal regions. In some embodiments, EMI shield layer 220 may be segmented in a manner similar to and corresponding to the thermal separation of thermal regions or zones 850, 860, 870, and/or 880 as illustrated in FIG. 8. Each such segment of EMI shield layer 220 may be coupled to another segment of EMI shield layer 220 and/or ground via conductors outside of wafer scale active thermal interposer device 130 (FIG. 1).

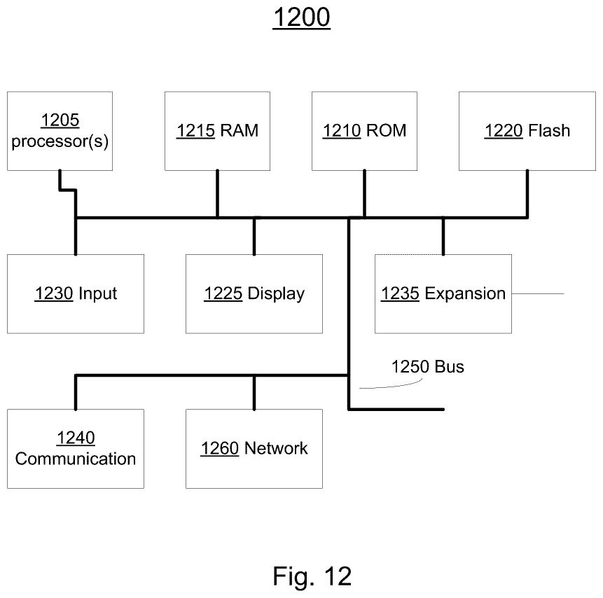

FIG. 12 illustrates a block diagram of an exemplary electronic system 1200, which may be used as a platform to implement and/or as a control system (thermal controller or test system) for embodiments of the present invention. Electronic system 1200 may be a “server” computer system, in some embodiments. Electronic system 1200 includes an address/data bus 1250 for communicating information, a central processor complex 1205 functionally coupled with the bus for processing information and instructions. Bus 1250 may comprise, for example, a Peripheral Component Interconnect Express (PCle) computer expansion bus, industry standard architecture (ISA), extended ISA (EISA), MicroChannel, Multibus, IEEE 796, IEEE 1196, IEEE 1496, PCI, Computer Automated Measurement and Control (CAMAC), MBus, Runway bus, Compute Express Link (CXL), and the like.

Central processor complex 1205 may comprise a single processor or multiple processors, e.g., a multi-core processor, or multiple separate processors, in some embodiments. Central processor complex 1205 may comprise various types of well known processors in any combination, including, for example, digital signal processors (DSP), graphics processors (GPU), complex instruction set (CISC) processors, reduced instruction set (RISC) processors, and/or very long word instruction set (VLIW) processors. Electronic system 1200 may also includes a volatile memory 1215 (e.g., random access memory RAM) coupled with the bus 1250 for storing information and instructions for the central processor complex 1205, and a non-volatile memory 1210 (e.g., read only memory ROM) coupled with the bus 1250 for storing static information and instructions for the processor complex 1205. Electronic system 1200 also optionally includes a changeable, non-volatile memory 1220 (e.g., NOR flash) for storing information and instructions for the central processor complex 1205 which can be updated after the manufacture of system 1200. In some embodiments, only one of ROM 1210 or Flash 1220 may be present.

Also included in electronic system 1200 of FIG. 12 is an optional input device 1230. Device 1230 can communicate information and command selections to the central processor 1200. Input device 1230 may be any suitable device for communicating information and/or commands to the electronic system 1200. For example, input device 1230 may take the form of a keyboard, buttons, a joystick, a track ball, an audio transducer, e.g., a microphone, a touch sensitive digitizer panel, eyeball scanner, and/or the like.

Electronic system 1200 may comprise a display unit 1225. Display unit 1225 may comprise a liquid crystal display (LCD) device, cathode ray tube (CRT), field emission device (FED, also called flat panel CRT), light emitting diode (LED), plasma display device, electro-luminescent display, electronic paper, electronic ink (e-ink) or other display device suitable for creating graphic images and/or alphanumeric characters recognizable to the user. Display unit 1225 may have an associated lighting device, in some embodiments.

Electronic system 1200 also optionally includes an expansion interface 1235 coupled with the bus 1250. Expansion interface 1235 can implement many well known standard expansion interfaces, including without limitation the Secure Digital Card interface, universal serial bus (USB) interface, Compact Flash, Personal Computer (PC) Card interface, CardBus, Peripheral Component Interconnect (PCI) interface, Peripheral Component Interconnect Express(PCI Express), mini-PCI interface, IEEE 1394, Small Computer System Interface (SCSI), Personal Computer Memory Card International Association (PCMCIA) interface, Industry Standard Architecture (ISA) interface, RS-232 interface, and/or the like. In some embodiments of the present invention, expansion interface 1235 may comprise signals substantially compliant with the signals of bus 1250.

A wide variety of well-known devices may be attached to electronic system 1200 via the bus 1250 and/or expansion interface 1235. Examples of such devices include without limitation rotating magnetic memory devices, flash memory devices, digital cameras, wireless communication modules, digital audio players, and Global Positioning System (GPS) devices.

System 1200 also optionally includes a communication port 1240. Communication port 1240 may be implemented as part of expansion interface 1235. When implemented as a separate interface, communication port 1240 may typically be used to exchange information with other devices via communication-oriented data transfer protocols. Examples of communication ports include without limitation RS-232 ports, universal asynchronous receiver transmitters (UARTs), USB ports, infrared light transceivers, ethernet ports, IEEE 1394, and synchronous ports.

System 1200 optionally includes a network interface 1260, which may implement a wired or wireless network interface. Electronic system 1200 may comprise additional software and/or hardware features (not shown) in some embodiments.

Various modules of system 1200 may access computer readable media, and the term is known or understood to include removable media, for example, Secure Digital (“SD”) cards, CD and/or DVD ROMs, diskettes and the like, as well as non-removable or internal media, for example, hard drives, solid state drive s (SSD), RAM, ROM, flash, and the like.

Embodiments in accordance with the present invention provide systems and methods for wafer scale active thermal interposer devices for use in controlling temperature of a die layout within a wafer DUT during testing thereof. In addition, embodiments in accordance with the present invention provide systems and methods for wafer scale active thermal interposer devices operable to control different portions of a wafer to different temperatures. Further, embodiments in accordance with the present invention provide systems and methods for wafer scale active thermal interposer devices that are compatible and complementary with existing systems and methods of testing integrated circuits.

Various embodiments of the invention are thus described. While the present invention has been described in particular embodiments, it should be appreciated that the invention should not be construed as limited by such embodiments, but rather construed according to the below claims.

In sum, the disclosed techniques overcome the limitations of traditional methods by incorporating thermal resistance structures into a wafer scale active thermal interposer device. The thermal resistance structures limit heat flow from one region to another region of the wafer scale active thermal interposer device. A wafer scale active thermal interposer device generally comprises multiple thermal regions. Each such thermal region may correspond to areas of a wafer device under test, e.g., a die, a portion of a die, or multiple dice. The individual areas of the wafer device under test may be controlled to different temperatures by independent control the thermal regions of the wafer scale active thermal interposer device. The thermal resistance structures impede heat flow from one region to another region of the wafer scale active thermal interposer device that might interfere with the independent control the thermal regions of the wafer scale active thermal interposer device. The thermal resistance structures may take a form of holes, trenches, and/or walls, in some embodiments.

At least one technical advantage of the disclosed techniques is that temperatures of different areas of a wafer device under test are better controlled in comparison to the conventional art. Another technical advantage of the disclosed techniques is that less unwanted heat flows from one region of a wafer scale active thermal interposer device to other regions of a wafer scale active thermal interposer device. The disclosed techniques further offer enhanced testing flexibility of testing different portions, e.g., different die of a wafer, of a wafer device under test at different temperatures.
1. In some embodiments, a wafer scale active thermal interposer (ATI) device for use in testing a wafer device under test (DUT) comprises a formation comprising one or more layers and comprising a plurality of thermal zones configured to apply thermal energy to a plurality of dice of said wafer DUT during said testing thereof and wherein said plurality of thermal zones corresponds to a die layout of said wafer DUT, a first thermal zone of said plurality of thermal zones configured to apply thermal energy to a first thermal region of said wafer DUT, a second thermal zone of said plurality of thermal zones configured to apply thermal energy to a second thermal region of said wafer DUT, wherein said second thermal zone is configured to control a temperature of said second thermal region of said wafer DUT independently of a temperature of said first thermal region, wherein said first thermal zone is configured to control a temperature of said first thermal region of said wafer DUT independently of a temperature of said second thermal region, and wherein said formation further comprises a plurality of thermal resistance structures located between said plurality of thermal zones, said plurality of thermal resistance structures configured to limit conductance of thermal energy between said plurality of thermal zones.
2. The ATI device of Clause 1 wherein said plurality of thermal zones covers said plurality of dice of said wafer DUT.
3. The ATI device of Clauses 1 or 2 wherein said first thermal zone corresponds to more than one die of said plurality of dice of said wafer DUT and less than said plurality of dice of said wafer DUT.
4. The ATI device of Clauses 1-3 wherein said first thermal zone corresponds to a single die of said plurality of dice of said wafer DUT.
5. The ATI device of Clauses 1-4 wherein said first thermal zone corresponds to a portion a single die of said plurality of dice of said wafer DUT.
6. The ATI device of Clauses 1-5 wherein said plurality of thermal resistance structures comprises a plurality of trenches formed in said formation and disposed between said plurality of thermal zones.
7. The ATI device of Clause 6 wherein said plurality of trenches is formed completely through of said one or more layers of said formation.
8. The ATI device of Clause 6 wherein said plurality of trenches is formed partially through said one or more layers of said formation.
9. The ATI device of Clauses 1-8 further comprising an EMI shield layer.
10. The ATI device of Clauses 1-9 wherein said plurality of thermal resistance structures comprises a plurality of structures raised above a surface of said formation and disposed between said plurality of thermal zones.
11. The ATI device of Clause 10 wherein said plurality of thermal resistance structures comprises a same material as a surface of said formation.
12. The ATI device of Clauses 1-11 wherein said plurality of thermal resistance structures comprises a plurality of substantially similar holes formed in said formation and disposed between said plurality of thermal zones.
13. The ATI device of Clauses 1-12 further comprising an EMI shield layer and wherein said EMI shield layer comprises conductive elements disposed in areas between a plurality of holes having non-circular cross sections.
14. In some embodiments, a system for testing circuits of an integrated circuit semiconductor wafer comprises a tester system for testing said circuits of said wafer, and a test stack coupled to said tester system, said test stack comprising a wafer probe for contacting a first surface of said wafer and for probing individual circuits of said circuits of said wafer, a thermal interposer device operable to contact a second surface of said wafer and comprising a plurality of heating zones corresponding to a die layout of said wafer and operable to selectively heat a plurality of regions of said wafer during said testing, wherein said thermal interposer device comprises a plurality of thermal resistance structures disposed between said plurality of heating zones and configured to limit conductance of thermal energy between said plurality of heating zones, a cold plate disposed adjacent to a surface of said thermal interposer device and operable to cool said wafer, and a thermal controller for selectively heating and maintaining temperatures of said plurality of regions of said wafer by controlling cooling of said cold plate and by controlling selective heating of said plurality of heating zones of said thermal interposer device.
15. The system of Clause 14 wherein said plurality of thermal resistance structures comprises a plurality of trenches formed in said thermal interposer device, said plurality of trenches disposed between said plurality of heating zones of said thermal interposer device.
16. The system of Clause 15 wherein said thermal interposer device comprises one or more layers and wherein said plurality of trenches is formed completely through said one or more layers of said thermal interposer device.
17. The system of Clause 15 wherein said thermal interposer device comprises one or more layers and wherein said plurality of trenches is formed partially through said one or more layers of said thermal interposer device.
18. The system of Clause 14 wherein said thermal interposer device further comprises an EMI shield layer.
19. The system of Clause 15 wherein said plurality of thermal resistance structures comprises a plurality of structure elements raised above a surface of said thermal interposer device, said plurality of structure elements disposed between said plurality of heating zones of said thermal interposer device.
20. The system of Clause 19 wherein said plurality of thermal resistance structures comprises a same material as a surface of said thermal interposer device.
21. The system of Clause 15 wherein said plurality of thermal resistance structures comprises a plurality of substantially similar holes formed in said thermal interposer device.
22. The system of Clause 21 wherein said thermal interposer device comprises an EMI shield layer and wherein said EMI shield layer comprises conductive elements disposed in areas between said plurality of substantially similar holes.
23. In some embodiments, a system for testing circuits of an integrated circuit semiconductor wafer comprises a tester system for testing said circuits of said wafer, and a test stack coupled to said tester system, said test stack comprising a wafer probe for contacting a top surface of said wafer and for probing individual circuits of said circuits of said wafer, a thermal interposer device operable to contact a bottom surface of said wafer and comprising a plurality of discretely controllable thermal zones, wherein each thermal zone of said plurality of discretely controllable thermal zones is operable to be discretely and selectively heated to selectively heat a corresponding area of said wafer, wherein said thermal interposer device comprises a plurality of thermal resistance structures operable to limit thermal energy conductance between said plurality of discretely controllable thermal zones, and a cold plate disposed under said thermal interposer device and operable to cool said wafer, and a thermal controller for selectively heating and maintaining temperatures of areas of said wafer by controlling cooling of said cold plate and by controlling heating of said plurality of discretely controllable thermal zones of said thermal interposer device.
24. In some embodiments, a system as described in Clause 23 wherein said wafer comprises a die layout comprises a plurality of dice and wherein further positions and shapes of said plurality of discretely controllable thermal zones are customized to said die layout of said wafer and wherein further said plurality of thermal resistance structures is disposed between said plurality of discretely controllable thermal zones.
25. In some embodiments, a system as described in Clause 24 wherein each thermal zone of said plurality of discretely controllable thermal zones corresponds to multiple dice of said die layout of said wafer.
26. In some embodiments, a system as described in Clause 24 wherein each thermal zone of said plurality of discretely controllable thermal zones corresponds to a single die of said die layout of said wafer.
27. In some embodiments, a system as described in Clause 24 wherein each die of said die layout of said wafer corresponds to multiple thermal zones of said plurality of discretely controllable thermal zones of said thermal interposer device.
28. The system as described in Clause 24 wherein said thermal interposer device comprises a plurality of traces traversing said thermal interposer device and operable to selectively heat and maintain temperatures of said plurality of discretely controllable thermal zones of said thermal interposer device responsive to said thermal controller.
29. In some embodiments, a method for testing circuits of an integrated circuit semiconductor wafer comprises testing said circuits of said wafer using a tester system, and in conjunction with performing said testing, selectively heating and maintaining temperatures of a plurality of areas of said wafer by using a thermal controller controlling a thermal interposer and a cold plate, both disposed in proximity of said wafer and wherein dimensions of said thermal interposer are customized for said wafer, and wherein said thermal interposer comprises a plurality of separately controllable thermal zones wherein each thermal zone of said plurality of separately controllable thermal zones is operable to be selectively heated and temperature maintained by said thermal controller, and wherein said thermal interposer further comprises a plurality of thermal resistance structures located between said plurality of separately controllable thermal zones, said plurality of thermal resistance structures is configured to limit conductance of thermal energy between said plurality of separately controllable thermal zones.
30. In some embodiments, a method as described in Clause 29 wherein said wafer comprises a die layout and wherein further positions and shapes of said plurality of separately controllable thermal zones of said thermal interposer are customized to said die layout.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method, or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods, and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions. While the preceding is directed to embodiments of the present disclosure, other and further embodiments of the disclosure may be devised without departing from the basic scope thereof, and the scope thereof is determined by the claims that follow.

We claim:

1. A wafer scale active thermal interposer (ATI) device for use in testing a wafer device under test (DUT), said ATI device comprising:
a formation comprising one or more layers and comprising a plurality of thermal zones configured to apply thermal energy to a plurality of dice of said wafer DUT during said testing thereof and wherein said plurality of thermal zones corresponds to a die layout of said wafer DUT;
a first thermal zone of said plurality of thermal zones configured to apply thermal energy to a first thermal region of said wafer DUT;
a second thermal zone of said plurality of thermal zones configured to apply thermal energy to a second thermal region of said wafer DUT,
wherein said second thermal zone is configured to control a temperature of said second thermal region of said wafer DUT independently of a temperature of said first thermal region,
wherein said first thermal zone is configured to control a temperature of said first thermal region of said wafer DUT independently of a temperature of said second thermal region, and
wherein said formation further comprises a plurality of thermal resistance structures located between said plurality of thermal zones, said plurality of thermal resistance structures configured to limit conductance of thermal energy between said plurality of thermal zones.

2. The ATI device of claim 1 wherein said plurality of thermal zones covers said plurality of dice of said wafer DUT.

3. The ATI device of claim 1 wherein said first thermal zone corresponds to more than one die of said plurality of dice of said wafer DUT and less than said plurality of dice of said wafer DUT.

4. The ATI device of claim 1 wherein said first thermal zone corresponds to a single die of said plurality of dice of said wafer DUT.

5. The ATI device of claim 1 wherein said first thermal zone corresponds to a portion a single die of said plurality of dice of said wafer DUT.

6. The ATI device of claim 1 wherein said plurality of thermal resistance structures comprises a plurality of trenches formed in said formation and disposed between said plurality of thermal zones.

7. The ATI device of claim 6 wherein said plurality of trenches is formed completely through of said one or more layers of said formation.

8. The ATI device of claim 6 wherein said plurality of trenches is formed partially through said one or more layers of said formation.

9. The ATI device of claim 1 further comprising an EMI shield layer.

10. The ATI device of claim 1 wherein said plurality of thermal resistance structures comprises a plurality of structures raised above a surface of said formation and disposed between said plurality of thermal zones.

11. The ATI device of claim 10 wherein said plurality of thermal resistance structures comprises a same material as a surface of said formation.

12. The ATI device of claim 1 wherein said plurality of thermal resistance structures comprises a plurality of substantially similar holes formed in said formation and disposed between said plurality of thermal zones.

13. The ATI device of claim 1 further comprising an EMI shield layer and wherein said EMI shield layer comprises conductive elements disposed in areas between a plurality of holes having non-circular cross sections.

14. A system for testing circuits of an integrated circuit semiconductor wafer, the system comprising:
a tester system for testing said circuits of said wafer; and
a test stack coupled to said tester system, said test stack comprising:
a wafer probe for contacting a first surface of said wafer and for probing individual circuits of said circuits of said wafer;
a thermal interposer device operable to contact a second surface of said wafer and comprising a plurality of heating zones corresponding to a die layout of said wafer and operable to selectively heat a plurality of regions of said wafer during said testing,
wherein said thermal interposer device comprises a plurality of thermal resistance structures disposed between said plurality of heating zones and configured to limit conductance of thermal energy between said plurality of heating zones;
a cold plate disposed adjacent to a surface of said thermal interposer device and operable to cool said wafer; and
a thermal controller for selectively heating and maintaining temperatures of said plurality of regions of said wafer by controlling cooling of said cold plate and by controlling selective heating of said plurality of heating zones of said thermal interposer device.

15. The system of claim 14 wherein said plurality of thermal resistance structures comprises a plurality of trenches formed in said thermal interposer device, said plurality of trenches disposed between said plurality of heating zones of said thermal interposer device.

16. The system of claim 15 wherein said thermal interposer device comprises one or more layers and wherein said plurality of trenches is formed completely through said one or more layers of said thermal interposer device.

17. The system of claim 15 wherein said thermal interposer device comprises one or more layers and wherein said plurality of trenches is formed partially through said one or more layers of said thermal interposer device.

18. The system of claim 14 wherein said thermal interposer device further comprises an EMI shield layer.

19. The system of claim 15 wherein said plurality of thermal resistance structures comprises a plurality of structure elements raised above a surface of said thermal interposer device, said plurality of structure elements disposed between said plurality of heating zones of said thermal interposer device.

20. The system of claim 19 wherein said plurality of thermal resistance structures comprises a same material as a surface of said thermal interposer device.

21. The system of claim 15 wherein said plurality of thermal resistance structures comprises a plurality of substantially similar holes formed in said thermal interposer device.

22. The system of claim 21 wherein said thermal interposer device comprises an EMI shield layer and wherein said EMI shield layer comprises conductive elements disposed in areas between said plurality of substantially similar holes.

23. A system for testing circuits of an integrated circuit semiconductor wafer, the system comprising:
a tester system for testing said circuits of said wafer; and
a test stack coupled to said tester system, said test stack comprising:
a wafer probe for contacting a top surface of said wafer and for probing individual circuits of said circuits of said wafer;
a thermal interposer device operable to contact a bottom surface of said wafer and comprising a plurality of discretely controllable thermal zones, wherein each thermal zone of said plurality of discretely controllable thermal zones is operable to be discretely and selectively heated to selectively heat a corresponding area of said wafer,
wherein said thermal interposer device comprises a plurality of thermal resistance structures operable to limit thermal energy conductance between said plurality of discretely controllable thermal zones; and
a cold plate disposed under said thermal interposer device and operable to cool said wafer; and
a thermal controller for selectively heating and maintaining temperatures of areas of said wafer by controlling cooling of said cold plate and by controlling heating of said plurality of discretely controllable thermal zones of said thermal interposer device.

24. A system as described in claim 23 wherein said wafer comprises a die layout comprising a plurality of dice and wherein further positions and shapes of said plurality of discretely controllable thermal zones are customized to said die layout of said wafer and wherein further said plurality of thermal resistance structures is disposed between said plurality of discretely controllable thermal zones.

25. A system as described in claim 24 wherein each thermal zone of said plurality of discretely controllable thermal zones corresponds to multiple dice of said die layout of said wafer.

26. A system as described in claim 24 wherein each thermal zone of said plurality of discretely controllable thermal zones corresponds to a single die of said die layout of said wafer.

27. A system as described in claim 24 wherein each die of said die layout of said wafer corresponds to multiple thermal zones of said plurality of discretely controllable thermal zones of said thermal interposer device.

28. The system as described in claim 24 wherein said thermal interposer device comprises a plurality of traces traversing said thermal interposer device and operable to selectively heat and maintain temperatures of said plurality of discretely controllable thermal zones of said thermal interposer device responsive to said thermal controller.

29. A method for testing circuits of an integrated circuit semiconductor wafer, the method comprising:
testing said circuits of said wafer using a tester system; and
in conjunction with performing said testing, selectively heating and maintaining temperatures of a plurality of areas of said wafer by using a thermal controller controlling a thermal interposer and a cold plate, both disposed in proximity of said wafer and wherein dimensions of said thermal interposer are customized for said wafer, and
wherein said thermal interposer comprises a plurality of separately controllable thermal zones wherein each thermal zone of said plurality of separately controllable thermal zones is operable to be selectively heated and temperature maintained by said thermal controller, and
wherein said thermal interposer further comprises a plurality of thermal resistance structures located between said plurality of separately controllable thermal zones, said plurality of thermal resistance structures is configured to limit conductance of thermal energy between said plurality of separately controllable thermal zones.

30. A method as described in claim 29 wherein said wafer comprises a die layout and wherein further positions and shapes of said plurality of separately controllable thermal zones of said thermal interposer are customized to said die layout.
